(19) United States
(12) Patent Application Publication
(10) Pub. No.: US 2010/0172058 A1
(43) Pub. Date: Jul. 8, 2010

(54) FLEXIBLE WIRING UNIT AND ELECTRONIC DEVICE

(75) Inventor: Akira Oikawa, Tokyo (JP)

Correspondence Address: DITTHAVONG MORI & STEINER, P.C., 918 Prince Street, Alexandria, VA, 22314, US

(73) Assignee: SUMITOMO BAKELITE CO., LTD., Tokyo (JP)

(21) Appl. No.: 12/602,098

(22) PCT Filed: Jun. 20, 2008
(86) PCT No.: PCT/JP2008/001596

§ 371 Date: Nov. 26, 2009

(30) Foreign Application Priority Data
Jun. 27, 2007 (JP) 2007-168806

(51) Int. Cl. G11B 21/16; H05K 1/00

(52) U.S. Cl. 360/245.9; 174/254; G9B/21.023

(57) ABSTRACT

A reciprocating motion of a head unit produces a change in front-to-back length of the lower face of a flexible substrate opposing a metal base. However, between the lower face of the flexible substrate and the upper face of the metal base opposing each other, a non-conductive substrate spacer of a predetermined plate thickness is constantly interposed. Such structure suppresses fluctuation in impedance of the flexible substrate arising from fluctuation in capacitance between the flexible substrate and the metal base, within a predetermined range. Consequently, with the structure that the moving heat unit is connected to the flexible substrate, a communication error of the flexible substrate, can be prevented.

### TECHNICAL FIELD

The present invention relates to a flat flexible wiring unit including a first linear portion, an intermediate linear portion, and a second linear portion continuously formed in a crank shape, and to an electronic device that utilizes the flexible wiring unit.

### BACKGROUND ART

Currently a disk drive unit, an example of the electronic device, is structured such that a head unit linearly reciprocates parallel to an upper face of a metal base. A conventional example of such electronic device will be described below, referring to FIG. 7.

The disk drive unit 100 exemplifying the electronic device includes a metal base 110, a head unit 120, a head moving mechanism (not shown), a disk drive mechanism 130, a flexible wiring unit 200, and so forth, as essential components.

As shown in FIG. 7(a), the metal base 110 is of a plate shape having a flat upper face. The disk drive mechanism 130 includes a driving motor 131, a disk retainer 132, and so on.

The driving motor 131 is fixed to the upper face of the metal base 110 such that the axial center is vertically oriented. The disk retainer 132 is rotatably supported by the driving motor 131 about the shaft thereof, and serves to retain a disk medium 140 in a parallel orientation to the upper face of the metal base 110.

The flexible wiring unit 200 includes a flexible substrate 210, a connector 220, a base end support member 230, and so on. The flexible substrate 210 is of a slender shape in a back-and-forth direction, and bent upward in a U-shape.

The flexible substrate 210 is provided with a head unit 120 attached to a tip portion thereof, and the head unit 120 is connected to an internal wiring (not shown). The connector 220 is attached to a base end portion of the flexible substrate 210, and connected to the internal wiring.

The base end support member 230 is mounted on the upper face of the metal base 210, and the base end portion of the flexible substrate 210 is attached to the upper face of the base end support member 230. To the connector 220, a driver circuit is provided through a communication cable (not shown).

In the disk drive unit 100 thus configured, the disk drive mechanism 130 rotatively drives the disk medium 140, and the head unit 120 reciprocates radially of the disk medium 140 and parallel to the lower face thereof.

To the head unit 120, the driver circuit is provided through the flexible substrate 210 of the flexible wiring unit 200, so that the driver circuit executes data reading and data writing from and in the disk medium 140, through the head unit 120.

In such disk drive unit 100, generally the flexible substrate 210 is of a single layer structure including only one layer of the internal wiring. This gives sufficient flexibility to the flexible substrate 210, thereby allowing the head unit 120 to move smoothly.

Since the base end support member 230 is provided at the base end portion of the flexible substrate 210 in such flexible wiring unit 200, the flexible substrate 210 can be easily handled despite its flexibility.

Regarding the electronic device configured as above, various proposals have been made (for example, a patented document 1 cited below). [Patented document 1] JP-A No. 2000-173200

### DISCLOSURE OF THE INVENTION

In the foregoing disk drive unit 100, the head unit 120 which reciprocates and the stationary driver circuit can make wire communication without disturbance through the flexible substrate 210 of the flexible wiring unit 200.

In such disk drive unit 100, however, the movement of the head unit 120 produces a change in front-to-back length of the lower face of the flexible substrate 210 opposing the metal base 110, as shown in FIG. 7(b). This results in fluctuation in impedance of the flexible substrate 210, because of fluctuation in capacitance between the flexible substrate 210 and the metal base 110.

However, the disk drive units that are recently developed are designed to read and write data with the head unit 120 at a higher signal frequency with a lower power. Accordingly, the fluctuation in impedance of the flexible substrate 210 may provoke an error of the head unit 120 in reading or writing data.

In particular, the flexible substrate 210 connected to the movable head unit 120 is of the single layer structure in order to secure sufficient softness. Such flexible substrate 210 is not provided with a shield layer, and hence exhibits prominent fluctuation in impedance.

The present invention has been accomplished in view of the foregoing problem, and provides a flexible wiring unit and an electronic device capable of preventing a wire communication error of a head unit of the electronic device.

According to the present invention, there is provided a flexible wiring unit comprising a flexible substrate of a slender shape in a back-and-forth direction, including an internal wiring provided longitudinally of the flexible substrate, and bent upward in a U-shape; a connector attached to a base end portion of the flexible substrate and connected to an internal wiring; a non-conductive base end support member connected via an upper face thereof to the base end portion of the flexible substrate; and a non-conductive substrate spacer of a predetermined plate thickness, disposed so as to oppose an entirety of a lower face of the flexible substrate under a state where a tip portion of the flexible substrate is located at a forward end of a predetermined stroke.

In the flexible wiring unit according to the present invention, therefore, a head unit can be attached, for example, to the tip portion of the flexible substrate, with the base end support member and the substrate spacer being mounted on an upper face of a metal base. Under such configuration, wire communication can be made without disturbance to the head unit which reciprocates, through the flexible substrate. The reciprocating motion of the head unit produces a change in front-to-back length of the lower face of the flexible substrate opposing the metal base. However, between the lower face of the flexible substrate and the upper face of the metal base opposing each other, the non-conductive substrate spacer of a predetermined plate thickness is constantly interposed. Such structure suppresses fluctuation in impedance of the flexible substrate arising from fluctuation in capacitance between the flexible substrate and the metal base, within a predetermined range.

According to the present invention, there is provided an electronic device including a head unit that linearly reciprocates parallel to an upper face of a metal base, comprising a metal base; a flexible substrate of a slender shape in a back-and-forth direction, and bent upward in a U-shape; the head unit attached to a tip portion of the flexible substrate and connected to an internal wiring; a head moving mechanism that causes the head unit to linearly reciprocate parallel to the upper face of the metal base; a connector attached to a base end portion of the flexible substrate and connected to the internal wiring; a non-conductive base end support member mounted on the upper face of the metal base, and connected via an upper face thereof to the base end portion of the flexible substrate; and a non-conductive substrate spacer of a predetermined plate thickness, mounted on the upper face of the metal base and disposed so as to oppose an entirety of a lower face of the flexible substrate under a state where the head unit is located at a forward end of a predetermined stroke.

It is to be noted that the constituents of the present invention do not necessarily have to be individually independent, but a plurality of constituents may form a piece of component; a constituent may be composed of a plurality of components; a constituent may be a part of another constituent; and a part of a constituent may also serve as a part of another constituent.

Although the present invention specifies the back and forth, and left and right direction, those are merely for convenience sake for simplifying the explanation of positional relations between the constituents of the present invention, and in no way intended to limit the direction in the manufacturing process or in the use of the product, in the execution of the present invention.

In the flexible wiring unit and the electronic device according to the present invention, for example a reciprocating motion of the head unit produces a change in front-to-back length of the lower face of the flexible substrate opposing the metal base. However, between the lower face of the flexible substrate and the upper face of the metal base opposing each other, the non-conductive substrate spacer of a predetermined plate thickness is constantly interposed. Such structure suppresses fluctuation in impedance of the flexible substrate arising from fluctuation in capacitance between the flexible substrate and the metal base, within a predetermined range. Consequently, a communication error of the head unit, which may be provoked by the fluctuation in impedance of the flexible substrate, can be prevented.

### BRIEF DESCRIPTION OF THE DRAWINGS

The above and other objects, features and advantages will become more apparent through a preferred embodiment described hereunder and the following accompanying drawings.

FIG. 1 is a schematic lateral view showing a structure of a flexible wiring unit according to an embodiment of the present invention;

FIG. 2 is a schematic perspective view showing a structure of an essential part of a disk drive unit exemplifying an electronic device;

FIGS. 3(a) and 3(b) are schematic cross-sectional lateral views showing a structure of an essential part of the disk drive unit;

FIG. 4 is a schematic cross-sectional lateral view showing a structure of an essential part of a disk drive unit according to a modified example;

FIG. 5 is a schematic cross-sectional lateral view showing a structure of an essential part of a disk drive unit according to another modified example;

FIG. 6 is a schematic perspective view showing a structure of an essential part of a disk drive unit according to still another modified example; and

FIGS. 7(a) and 7(b) are cross-sectional plan view showing an internal structure of an essential part of a disk drive unit exemplifying a conventional electronic device.

### BEST MODE FOR CARRYING OUT THE INVENTION

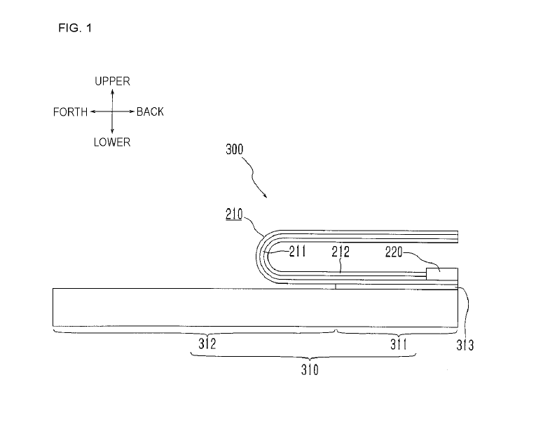

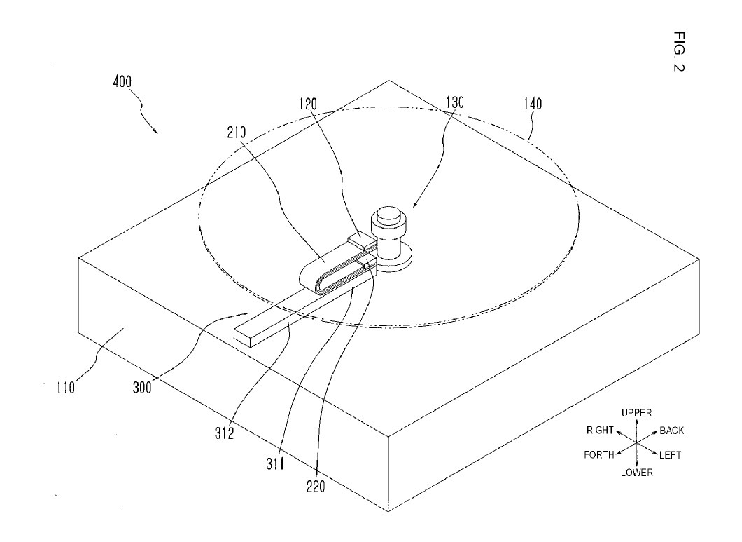

An embodiment of the present invention will be described hereunder, referring to FIGS. 1 to 3(b). The description of the embodiment refers to back and forth, left and right, and upper and lower directions, as shown in the drawings. It should be noted, however, that those directions are merely for convenience sake for simplifying the description, and in no way intended to limit the direction in the manufacturing process or in the use of the product, in the execution of the present invention.

A disk drive unit 400, exemplifying the electronic device according to this embodiment, includes a metal base 110, a head unit 120, a head moving mechanism (not shown), a disk drive mechanism 130, a flexible wiring unit 300, and so forth as essential components.

The metal base 110 is of a plate shape having a flat upper face. The disk drive mechanism 130 includes a driving motor 131, a disk retainer 132, and so on. The driving motor 131 is fixed to the upper face of the metal base 110 such that the axial center is vertically oriented. The disk retainer 132 is rotatably supported by the driving motor 131 about the shaft thereof, and serves to retain a disk medium 140 in a parallel orientation to the upper face of the metal base 110.

The flexible wiring unit 300 includes a flexible substrate 210, a connector 220, a base end support member 311, a substrate spacer 312, and so on. The flexible substrate 210 is of a slender shape in a back-and-forth direction, and bent upward in a U-shape.

The flexible substrate 210 is provided with a head unit 120 attached to a tip portion thereof, and the head unit 120 is connected to an internal wiring (not shown). The connector 220 is attached to a base end portion of the flexible substrate 210, and connected to the internal wiring.

The base end support member 311 is formed of a non-conductive polyethylene terephthalate (PET) or the like in a predetermined plate thickness, and connected via the upper face thereof to the base end portion of said flexible substrate 210, and mounted on the upper face of the metal base 110.

The substrate spacer 312 is also formed of a non-conductive PET or the like in a predetermined plate thickness, and mounted on the upper face of the metal base 110, in a region ahead of the base end support member 311. The substrate spacer 312 is formed in such a shape that opposes an entirety of the lower face of the flexible substrate 210 under a state where the head unit 120 is located at the forward end of a predetermined stroke.

It is to be noted that, in the flexible wiring unit 300 according to this embodiment, the base end support member 311 and the substrate spacer 312 are integrally formed as a single-piece resin plate member 310. On the upper face of the base end support member 311 thus formed, the base end portion of the flexible substrate 210 is fixed via an adhesive layer 313.

The flexible substrate 210 is of a single layer structure including only one layer of the internal wiring. On the upper face of the flexible substrate 210, a conductive shield layer 211 and a non-conductive insulating layer 212 are provided, by application of a conductive material and an insulating material. To the connector 220, a driver circuit is provided through a communication cable (not shown).

With the foregoing structure, in the disk drive unit 400 according to this embodiment, the disk drive mechanism 130 rotatively drives the disk medium 140, and the head unit 120 reciprocates radially of the disk medium and parallel to the lower face thereof, as in the conventional example of the disk drive unit 100.

To the head unit 120 the driver circuit is provided through the flexible substrate 210 of the flexible wiring unit 300, so that the driver circuit executes data reading and data writing from and in the disk medium 140, through the head unit 120.

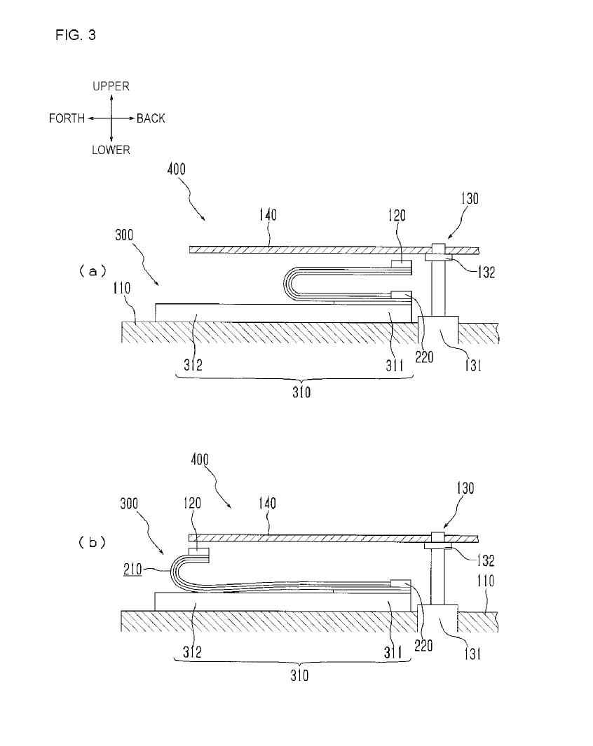

In the disk drive unit 400 according to this embodiment also, the movement of the head unit 120 produces a change in front-to-back length of the lower face of the flexible substrate 210 opposing the metal base 110, as shown in FIG. 3(b).

The flexible substrate 210 is of the flexible single layer structure including only one layer of the internal wiring, in order not to disturb the smooth movement of the head unit 120. The flexible substrate 210 of such single layer structure is not provided with a solid shield layer constituted of a metal foil or the like, on the lower face of the wiring layer. Accordingly, the change in front-to-back length of the lower face of the flexible substrate 210 opposing the metal base 110, produced by the movement of the head unit 120, leads to the drawback of fluctuation in impedance of the flexible substrate 210.

In the disk drive unit 400 according to this embodiment, however, unlike the conventional example as the disk drive unit 100, the non-conductive substrate spacer 312 of a predetermined plate thickness is constantly interposed between the lower face of the flexible substrate and the upper face of the metal base opposing each other, as stated above.

Such structure suppresses fluctuation in impedance of the flexible substrate 210 arising from fluctuation in capacitance between the flexible substrate 210 and the metal base 110, within a predetermined range. Consequently, a communication error of the head unit 120, which may be provoked by the fluctuation in impedance of the flexible substrate 210, can be prevented.

Moreover, in the flexible wiring unit 300 of the disk drive unit 400 according to this embodiment, the base end support member 311 and the substrate spacer 312 are integrally formed. Such simple structure provides high productivity, and assures accurate positioning of the substrate spacer 312 at the designated position.

It is to be understood that the present invention is not limited to the foregoing embodiment, but encompasses various modified examples within the scope and spirit of the present invention. To cite a few examples, although the embodiment exemplifies the structure that the disk medium 140 is removably set on the disk drive unit 400, the disk medium may be fixed on the disk drive unit (not shown).

Also, the foregoing embodiment exemplifies the disk drive unit 400 in which the entirety of the flexible substrate 210 bent in the U-shape is located on one side of the disk medium 140. However, the disk drive unit maybe configured such that the disk medium is located inside the U-shaped bent portion of the flexible substrate 210 (not shown).

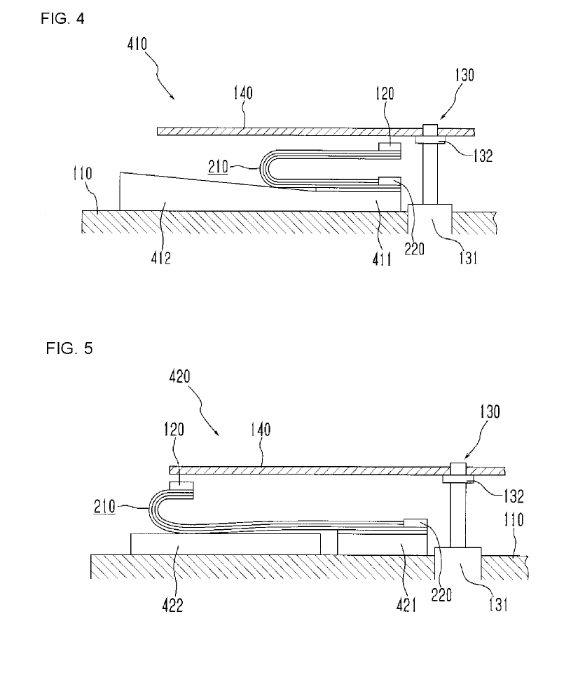

Further, the embodiment exemplifies the structure that the substrate spacer 312 of the flexible wiring unit 300 is formed in a uniform plate thickness which is the same as that of the base end support member 311. However, as a disk drive unit 410 exemplifying the electronic device shown in FIG. 4, a substrate spacer 412 may have a different plate thickness from that of a base end support member 411. Alternatively, as a disk drive unit 420 exemplifying the electronic device shown in FIG. 5, a base end support member 421 and a substrate spacer 422 may be formed in separate pieces.

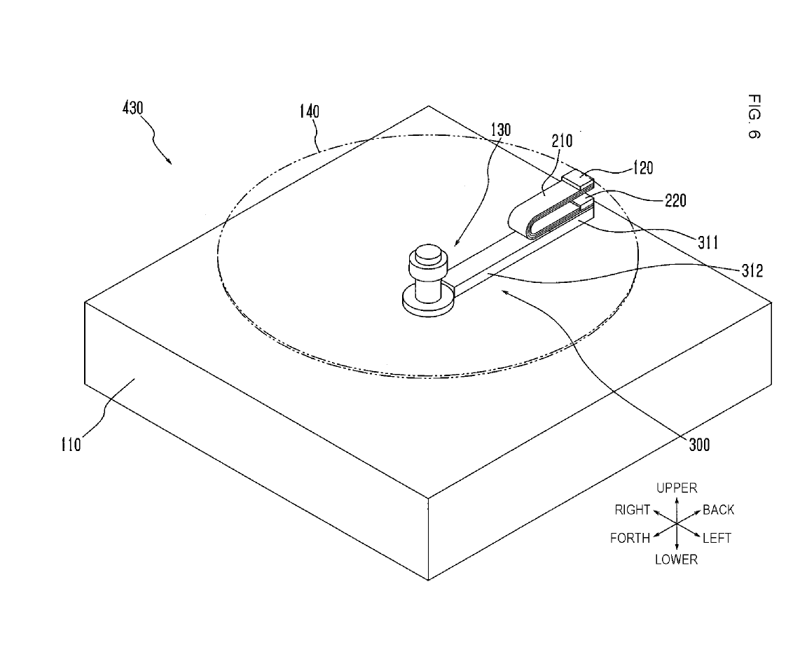

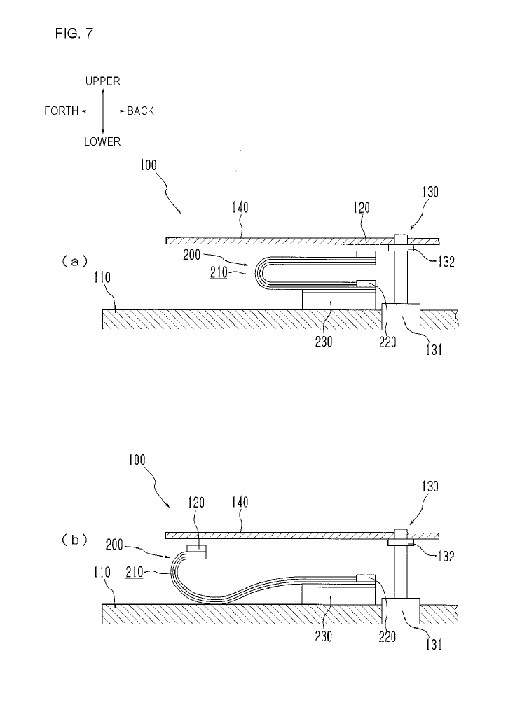

Further, the embodiment exemplifies the structure that the disk drive mechanism 130 rotatably supporting the disk medium 140 about the shaft thereof is located at a backward position of the flexible wiring unit 300. However, as a disk drive unit 430 exemplifying the electronic device shown in FIG. 6, the disk drive mechanism 130 may be located ahead of the flexible wiring unit 300.

In this case, the connector 220 of the flexible wiring unit 300 is located closer to an outer periphery of the disk drive unit 430, which makes it easier to connect the communication cable (not shown) to the connector 220.

Still further, the embodiment exemplifies the structure that the flexible wiring unit 300 is mounted on the metal base 110 of the disk drive unit 400, thus to be utilized for wire connection to the head unit 120.

However, the flexible wiring unit 300 according to this embodiment may be utilized for various other purposes, than the wire connection to the head unit 120 in the disk drive unit 400 (not shown).

Naturally, the foregoing embodiment and the plurality of modified examples may be combined as far as the ideas are not contradictory. Although the structure of each part in the embodiment and the modified examples is specifically described, such structure may be modified in various manners as far as the functions according to the present invention are satisfied.

1. A flexible wiring unit, comprising:
a flexible substrate of a slender shape in a back-and-forth direction, including an internal wiring provided longitudinally of said flexible substrate, and bent upward in a U-shape;
a connector attached to a base end portion of said flexible substrate and connected to an internal wiring;
a non-conductive base end support member connected via an upper face thereof to said base end portion of said flexible substrate; and
a non-conductive substrate spacer of a predetermined plate thickness, disposed so as to oppose an entirety of a lower face of said flexible substrate under a state where a tip portion of said flexible substrate is located at a forward end of a predetermined stroke.

2. The flexible wiring unit according to claim 1, wherein said base end support member and said substrate spacer are integrally formed.

3. The flexible wiring unit according to claim 1, wherein said flexible substrate is of a single layer structure including only one layer of said internal wiring.

4. The flexible wiring unit according to claim 1,
wherein a head unit that reciprocates parallel to an upper face of a metal base is attached to a tip portion of said flexible substrate, and connected to said internal wiring; and
said base end support member is mounted on an upper face of said metal base.

5. An electronic device in which a head unit linearly reciprocates parallel to an upper face of a metal base, comprising:
said metal base;
a flexible substrate of a slender shape in a back-and-forth direction, and bent upward in a U-shape;
said head unit attached to a tip portion of said flexible substrate and connected to an internal wiring;
a head moving mechanism that causes said head unit to linearly reciprocate parallel to said upper face of said metal base;
a connector attached to a base end portion of said flexible substrate and connected to said internal wiring;
a non-conductive base end support member mounted on said upper face of said metal base, and connected via an upper face thereof to said base end portion of said flexible substrate; and
a non-conductive substrate spacer of a predetermined plate thickness, mounted on said upper face of said metal base and disposed so as to oppose an entirety of a lower face of said flexible substrate under a state where said head unit is located at a forward end of a predetermined stroke.

6. The electronic device according to claim 5, wherein said base end support member and said substrate spacer are integrally formed.

7. The electronic device according to claim 5, wherein said flexible substrate is of a single layer structure including only one layer of said internal wiring.
